(19) United States
(12) Patent Application Publication
(10) Pub. No.: US 2015/0147258 A1
(43) Pub. Date: May 28, 2015

(54) SINGLE CRYSTAL SILICON INGOT AND WAFER, AND APPARATUS AND METHOD FOR GROWING SAID INGOT

(71) Applicant: LG SILTRON INCORPORATED, Gumi-si, Gyeongsangbuk-do (KR)

(72) Inventors: Young Ho Hong, Gumi-si (KR); Jung Ha Hwang, Gumi-si (KR); Il Seon Cha, Gumi-si (KR)

(73) Assignee: LG SILTRON INCORPORATION a corporation

(21) Appl. No.: 14/402,405

(22) PCT Filed: Apr. 2, 2013
(86) PCT No.: PCT/KR2013/002710

§ 371 Date: Nov. 20, 2014

(30) Foreign Application Priority Data
May 23, 2012 (KR) 10-2012-0054652
May 23, 2012 (KR) 10-2012-0054653
May 23, 2012 (KR) 10-2012-0054654

(51) Int. Cl. C30B 29/06; C30B 30/04; C30B 15/14

(52) U.S. Cl. CPC C30B 29/06; C30B 15/14; C30B 30/04
USPC 423/348; 117/217; 117/32

(57) ABSTRACT

The single crystal silicon ingot and wafer of one embodiment has a transition region formed therein which predominantly has crystal defects of 10 nm to 30 nm in size from among crystal defects included in at least one region of a vacancy predominant non-defective region and an interstitial predominant non-defective region.

### TECHNICAL FIELD

Embodiments relate to single-crystal silicon ingots and wafers, and apparatuses and methods of growing the ingots.

### BACKGROUND ART

General frequently used methods of manufacturing silicon wafers include Floating Zone (“FZ”) or CZochralski (“CZ”) methods. Growth of single-crystal silicon ingots by FZ methods, however, has several problems, such as difficulty in manufacturing large-diameter silicon wafers and considerably expensive process costs. Therefore, growth of single-crystal silicon ingots by CZ methods is prevalent.

With such a CZ method, after polycrystalline silicon is charged into a quartz crucible and molten via heating of a graphite heating element, a seed crystal is dipped into the resulting silicon melt to cause crystallization at an interface of the silicon melt and then pulled while being rotated, thereby completing growth of a single-crystal silicon ingot. Thereafter, the grown single-crystal silicon ingot is subjected to slicing, etching, and polishing so as to be shaped into a wafer.

FIG. 1 is a view schematically showing distribution of crystal defect regions based on a V/G value upon growth of a single-crystal silicon ingot. Here, “V” is a pulling rate of a single-crystal silicon ingot and “G” is a vertical temperature gradient of a melt-solid interface.

According to Voronkov's theory, when a single-crystal silicon ingot is pulled at high speed and at a high V/G value exceeding or equal to a critical value, the single-crystal silicon ingot is grown to have a vacancy-rich region (hereinafter referred to as “V region”) including defects caused by void. That is, the V region is a region with excessive vacancies due to silicon atom shortage.

In addition, when a single-crystal silicon ingot is pulled under the growth condition that a V/G value is smaller than the critical value, the single-crystal silicon ingot is grown to have an O-band region in which Oxidation induced Stacking Faults (OSFs) are present.

In addition, when a single-crystal silicon ingot is pulled at low speed and under the growth condition that a V/G value is further decreased, the single-crystal silicon ingot is grown to have an interstitial region (hereafter referred to as “I region”) due to dislocation loops produced by self-interstitial silicon agglomeration. That is, the I region is a region with excessive silicon self-interstitial agglomerates due to silicon atom surplus.

Provided between the V region and the I region are a vacancy predominant non-defective region (hereinafter referred to as “VDP region”) in which vacancies predominate and an interstitial predominant non-defective region (hereinafter referred to as “IDP region”) in which interstitials predominate. Although the VDP region and the IDP region are the same in that these regions have no silicon atom shortage or surplus, they have a difference in that the VDP region includes oxygen precipitate nuclei, whereas the IDP region does not include oxygen precipitate nuclei.

There may be a small void region that belongs to the O-band region and has vacancy-type microdefect, for example, Direct Surface Oxide Defects (DSODs).

In this case, to grow the single-crystal ingot including the VDP region and the IDP region, it is necessary to maintain a corresponding V/G value during growth of the single-crystal silicon ingot. To this end, during growth of the single-crystal silicon ingot, a silicon wafer is cut away from the ingot that is being grown, and crystal defect evaluation of the cut wafer is performed to check whether the ingot is being grown in a desired manner at the corresponding V/G value. Then, the V/G value is adjusted based on the checked result and the single-crystal ingot is grown to include the adjusted VDP region or the IDP region.

Examples of methods of evaluating crystal defects of wafers include Reactive Ion Etching (RIE), copper (Cu) deposition, a Cu haze method and the like.

Meanwhile, control and management of micro crystal defects caused during growth of a single-crystal silicon ingot are becoming very important due to gradual width reduction and higher integration of semiconductor devices. For example, there is a demand for growth of an ingot that has only micro crystal defects having a desired size even under the growth condition of non-defective regions such as VDP and IDP regions. In particular, Dynamic Random Access Memory (DRAM), NAND flash memory and the like have a width of 20 nm or less, thus requiring silicon wafers having crystal defects smaller than 20 nm.

However, the aforementioned conventional crystal defect evaluation methods provide detection of crystal defects greater than 30 nm and cannot properly evaluate crystal defects smaller than 30 nm. That is, the conventional crystal defect evaluation methods may indiscriminately evaluate crystal defects smaller than 30 nm as defects having the same size. Hence, it is difficult to manufacture silicon wafers or ingots having crystal defects smaller than 30 nm, for example, having a size of 10 nm to 29 nm.

### DISCLOSURE

### Technical Problem

One embodiment provides single-crystal silicon ingots and wafers having micro crystal defects smaller than 30 nm.

Another embodiment provides apparatuses and methods of growing single-crystal silicon ingots for manufacture of silicon wafers having micro crystal defects.

### Technical Solution

In one embodiment, a single-crystal silicon ingot and wafer includes a transition region having predominant crystal defects having a size of 10 nm to 30 nm among crystal defects included in at least one of a vacancy predominant non-defective region and an interstitial predominant non-defective region.

The crystal defects having a size of 10 nm to 30 nm makes up above 50% of all crystal defects included in the transition region.

The crystal defects having a size of 10 nm to 30 nm makes up 70% or more of all crystal defects included in the transition region.

The transition region includes no ring-shaped oxidation induced stacking faults.

The single-crystal silicon ingot and wafer is manufactured by a czochralski method.

The crystal defects included in the transition region have a size of 10 nm to 19 nm.

The interstitial predominant non-defective region occupies 100x % of the entire transition region (here, 0≦x≦1), and the vacancy predominant non-defective region may occupy 100(1−x) % of the entire transition region, in the single-crystal silicon ingot and wafer.

The interstitial predominant non-defective region occupies 70% or more of the entire transition region on the basis of a diameter of the single-crystal silicon ingot and wafer.

The vacancy predominant non-defective region occupies 30% or less of the entire transition region on the basis of a diameter of the single-crystal silicon ingot and wafer.

The vacancy predominant non-defective region of the transition region is located at the edge of the single-crystal silicon ingot and wafer, and the interstitial predominant non-defective region of the transition region may be located at the center of the single-crystal silicon ingot and wafer inside the edge.

The vacancy predominant non-defective region occupies 70% or more of the entire transition region on the basis of a diameter of the single-crystal silicon ingot and wafer.

The interstitial predominant non-defective region occupies 30% or less of the entire transition region on the basis of a diameter of the single-crystal silicon ingot and wafer.

The interstitial predominant non-defective region of the transition region is located at the edge of the single-crystal silicon ingot and wafer, and the vacancy predominant non-defective region of the transition region is located at the center of the single-crystal silicon ingot and wafer inside the edge.

The size of the crystal defects included in the transition region is detectable by a Magics method.

The size of the crystal defects included in the transition region is detectable by the Magics method, under a state without thermal treatment of the single-crystal silicon ingot and wafer.

The crystal defects having a size of 10 nm to 19 nm occurs in pixels No. 1 of an image captured by the Magics method.

In another embodiment, an apparatus of growing a single-crystal silicon ingot includes a crucible configured to receive a silicon melt therein, a heater installed around the crucible to apply heat to the crucible and a magnetic field generator configured to apply a magnetic field to the crucible such that a maximum magnetic plane (MGP) is created at a position determined according to a position of a maximum heat radiation point of the heater.

The apparatus of growing the single-crystal silicon ingot further includes a first controller configured to control the heater so as to change the position of the maximum heat radiation point; and a second controller configured to control the magnetic field generator so as to create the MGP at a position adjusted according to the changed position of the maximum heat radiation point.

The heater performs uniform heat radiation in the vertical direction or is configured to adjust the radiation amount of heat in the vertical direction.

The MGP is located lower than the position of the maximum heat radiation point.

The MGP is located lower than the position of the maximum heat radiation point by 20% to 40% on the basis of an interface of the silicon melt.

The MGP is located lower than the interface of the silicon melt by 50 mm to 300 mm.

The magnetic field applied to the crucible by the magnetic field generator may have a strength of 2000 gauss to 3400 gauss.

The single-crystal silicon ingot to be grown may have a target pulling rate range of 0.010 mm/min to 0.030 mm/min.

In another embodiment, a method of growing a single-crystal silicon ingot, performed by an apparatus of growing a single-crystal silicon ingot including a crucible configured to receive a silicon melt therein, a heater installed around the crucible to apply heat to the crucible and a magnetic field generator configured to apply a magnetic field to the crucible, includes determining a position of a maximum heat radiation point of the heater, determining a position of a maximum magnetic plane (MGP) according to the determined position of the maximum heat radiation point; and applying the magnetic field to the crucible so as to create the MGP at the determined position.

The method of growing the single-crystal silicon ingot further includes adjusting, when the position of the maximum heat radiation point is changed, a position of the MGP according to the changed position of the maximum heat radiation point; and creating the MGP at the adjusted position by applying the magnetic field to the crucible.

The magnetic field is applied to the crucible so as to create the MGP at a position lower than the position of the maximum heat radiation point.

The magnetic field is applied to the crucible so as to create the MGP at a position lower than the position of the maximum heat radiation point by 20% to 40% on the basis of an interface of the silicon melt.

The magnetic field is applied to the crucible so as to create the MGP at a position lower than an interface of the silicon melt by 50 mm to 300 mm.

The magnetic field applied to the crucible by the magnetic field generator may have a strength of 2000 gauss to 3400 gauss.

The single-crystal silicon ingot to be grown may have a target pulling rate range of 0.010 mm/min to 0.030 mm/min.

In another embodiment, an apparatus of growing a single-crystal silicon ingot includes 33. a crucible configured to receive a silicon melt therein for growth of the single-crystal silicon ingot; a heater configured to apply heat to the crucible to cause silicon in the crucible to be molten; a hoist configured to pull the single-crystal silicon ingot while rotating the ingot; a spin rate calculator configured to calculate a spin rate of the single-crystal silicon ingot; a first comparator configured to compare the calculated spin rate with a target spin rate and to output the comparison result as a spin rate error value; a flow rate controller configured to adjust, according to the spin rate error value, a flow rate of the silicon melt at a location where a diameter of the single-crystal silicon ingot is sensed; and a diameter sensor configured to sense the diameter of the single-crystal silicon ingot.

The apparatus of growing the single-crystal silicon ingot further includes a second comparator configured to compare the sensed diameter with a target diameter and to output the comparison result as a diameter error value, and the hoist pulls the single-crystal silicon ingot at a pulling rate changed according to the diameter error value while rotating the ingot.

In a further embodiment, a method of growing a single-crystal silicon ingot, performed by an apparatus of growing a single-crystal silicon ingot including a crucible configured to receive a silicon melt therein for growth of the single-crystal silicon ingot, a heater configured to apply heat to the crucible to cause silicon in the crucible to melt, and a hoist configured to pull the single-crystal silicon ingot while rotating the ingot, include measuring a spin rate of the single-crystal silicon ingot; determining a spin rate error value by comparing the measured spin rate with a target spin rate; adjusting, according to the spin rate error value, a flow rate of the silicon melt at a location where a diameter of the single-crystal silicon ingot is sensed; and sensing the diameter of the single-crystal silicon ingot.

The method of growing the single-crystal silicon ingot further includes determining a diameter error value by comparing the sensed diameter with a target diameter; and changing, according to the diameter error value, a pulling rate of the single-crystal silicon ingot to be grown.

The adjusting includes reducing the flow rate when the measured spin rate is greater than the target spin rate.

The location where the diameter is sensed corresponds to a meniscus of the silicon melt, and flow of the silicon melt at the meniscus is stabilized by reducing the flow rate of the silicon melt.

The single-crystal silicon ingot to be grown may have a pulling rate range of 0.020 mm/min to 0.030 mm/min.

### Advantageous Effects

High-quality single-crystal silicon ingots and wafers for semiconductors according to embodiments may be formed to include a transition region having crystal defects smaller than 30 nm, for example, having a size of 10 nm to 19 nm because detection of micro crystal defects smaller than 30 nm may be accomplished using a Magics method. The high-quality single-crystal silicon ingots and wafers may be used in semiconductor devices having a reduced width of 20 nm or less.

In addition, apparatuses and methods of growing single-crystal silicon ingots according to embodiments may accomplish more accurate control of a pulling rate of a single-crystal silicon ingot because the pulling rate is controlled after stabilizing flow of a silicon melt at a meniscus where a diameter of the single-crystal silicon ingot is sensed. In addition, since a position of the maximum magnetic field plane is determined based on a position of the maximum heat radiation point and the strength of a magnetic field is appropriately adjusted to control convection of the silicon melt, vacancy-interstitial recombination may be improved, which may increase a margin of an IDP region. Hence, it is possible to increase productivity and a growth rate of ingots owing to creation of an environment suitable for production of silicon wafers having crystal defects smaller than or equal to 20 nm, i.e. improvement of repeatability of manufacture of high-quality silicon wafers as described above.

### DESCRIPTION OF DRAWINGS

FIG. 1 is a view schematically showing distribution of crystal defect regions based on a V/G value upon growth of a single-crystal silicon ingot.

FIG. 2 is a view showing an apparatus of growing a single-crystal ingot according to an embodiment.

FIG. 3 is a view showing a growth rate of a single-crystal silicon ingot and distribution of crystal defects according to the present embodiment.

FIG. 4 is a plan view showing a single-crystal silicon ingot and wafer according to one embodiment.

FIG. 5 is a plan view showing a single-crystal silicon ingot and wafer according to another embodiment.

FIG. 6a is a plan view of a wafer sample after applying a Cu haze method to the wafer sample, and FIGS. 6b and 6c show images of wafer samples captured by a Magics method.

FIG. 7 is a TEM analysis graph showing a relationship between defect volumes and pixels of an image acquired by a Magics method.

FIG. 8 shows an image of crystal defects corresponding to pixels No. 1 captured using a TEM.

FIG. 9 is graph showing a histogram of pixels.

FIG. 10 is a flowchart explaining a method of growing a single-crystal silicon ingot according to one embodiment.

FIGS. 11a and 11b are graphs showing variation in the pulling rate of an ingot.

FIG. 12 is a view showing ranges of the pulling rate according to the related art and the present embodiment.

FIG. 13 is a flowchart explaining a method of growing a single-crystal silicon ingot according to another embodiment.

FIG. 14a shows the maximum value of a margin of an IDP region based on an MGP position value, and FIG. 14b shows a 70% value of the maximum value of a margin of an IDP region based on an MGP position value.

FIG. 15a shows the maximum value of a margin of an IDP region based on the strength of a magnetic field, and FIG. 15b shows a 70% value of the maximum value of a margin of an IDP region based on the strength of a magnetic field.

### MODE FOR INVENTION

Hereinafter, in order to describe the present invention embodiments will be described in detail with reference to the accompanying drawings to improve understanding of the present invention. However, various modifications of the embodiments are possible, and the technical sprit of the present invention is not constructed as being limited to the embodiments. The embodiments of the present invention are provided to explain the disclosure to those skilled in the art.

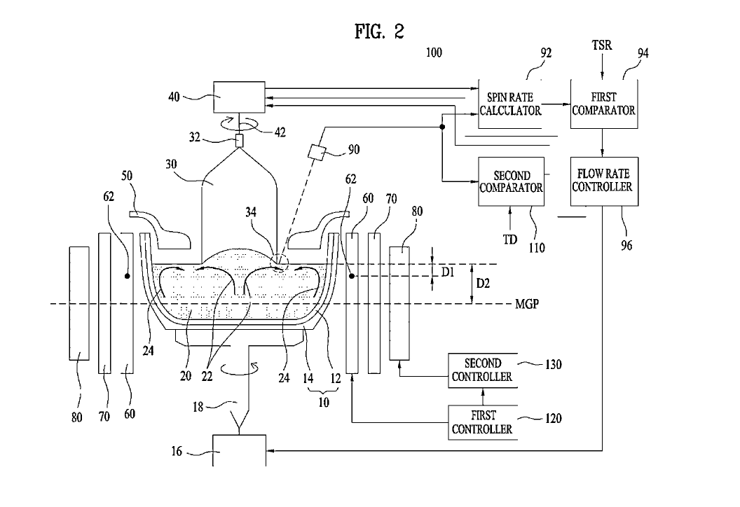

FIG. 2 is a view showing an apparatus of growing a single-crystal ingot, designated by reference numeral 100, according to an embodiment.

The single-crystal ingot growth apparatus 100 shown in FIG. 2 includes a crucible 10, a support shaft drive unit 16, a rotatable support shaft 18, a silicon melt 20, an ingot 30, a seed crystal 32, a wire hoist 40, a pull wire 42, a heat-shield member 50, a heater 60 arranged around the crucible 10, an insulator 70, a magnetic field generator 80, a diameter sensor 90, a spin rate calculator 92, a first comparator 94, a flow rate controller 96, a second comparator 110, and first and second controllers 120 and 130.

Referring to FIG. 2, the single-crystal silicon ingot growth apparatus 100 according to the present embodiment is configured to grow a single-crystal silicon ingot 30 via a CZ method as described below.

First, a high-purity polycrystalline silicon raw material is heated above a melting point thereof in the crucible 10 by the heater 60, thereby being changed into the silicon melt 20. In this case, the crucible 10, in which the silicon melt 20 is accommodated, has a dual structure including a quartz inner shell 12 and a graphite outer shell 14.

Thereafter, the hoist 40 releases the pull wire 42 such that a tip end of the seed crystal 32 is brought into contact with or is dipped in approximately the center of a surface of the silicon melt 20. In this case, a seed chuck (not shown) may be used to hold the silicon seed crystal 32.

Thereafter, the support shaft drive unit 16 rotates the rotatable support shaft 18 of the crucible 20 in a direction designated by the arrow and, simultaneously, the hoist 40 pulls the ingot 30 while rotating the ingot 30 using the pull wire 42 so as to grow the ingot. In this case, a pulling rate V and a temperature gradient G (ΔG) of the ingot 30 are adjusted to complete the cylindrical single-crystal silicon ingot 30.

The heat-shield member 50 is located between the single-crystal silicon ingot 30 and the crucible 10 to surround the ingot 30 and serves to prevent heat radiation from the ingot 30.

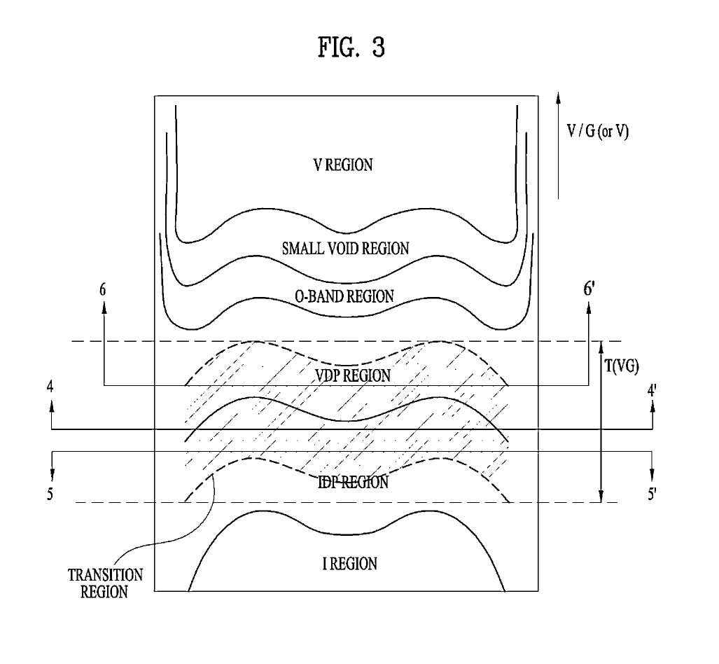

FIG. 3 is a view showing a growth rate of a single-crystal silicon ingot and distribution of crystal defects according to the present embodiment.

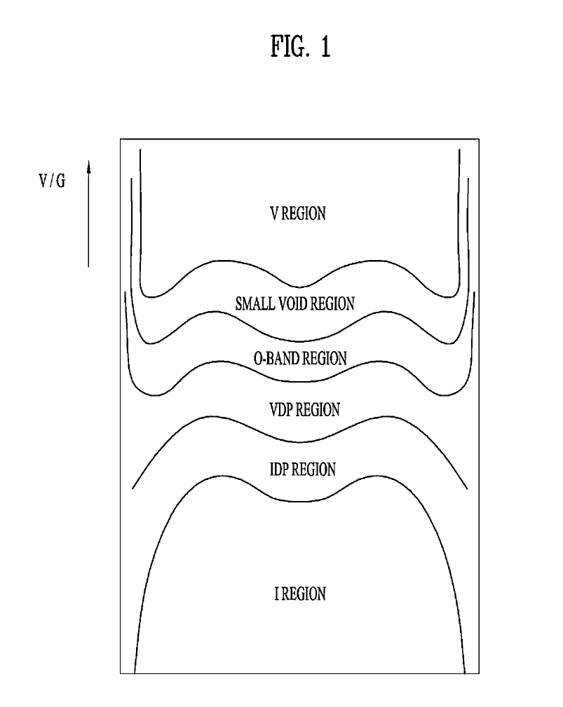

Defect distribution of a single-crystal silicon ingot shown in FIG. 3 is identical to defect distribution of a single-crystal silicon ingot shown in FIG. 1 except for it further defines a transition region and, therefore, a detailed description related to a V region, a small void region, an O-band region, a VDP region, an IDP region and an I region will be omitted below. Here, the transition region refers to a region in which crystal defects having a size of 10 nm to 30 nm among crystal defects included in at least one of a VDP region and an IDP region predominate. Whether specific defects predominate may be determined when the specific defects make up 50% or more of total defects. That is, crystal defects having a size of 10 nm to 30 nm may make up 50% or more of all crystal defects included in the transition region. In other words, it can be said that crystal defects having a size of 10 nm to 30 nm may occupy k % or more (here, 50≦k≦100) of all crystal defects included in the transition region.

For example, the crystal defects predominantly included in the transition region may have a size of 10 nm to 19 nm. The transition region may not include crystal defects that belong to an O-band region that is a ring-shaped oxidation induced stacking fault region or I region.

When the apparatus shown in FIG. 2 is configured to grow the ingot 30 at an arbitrary V/G value selected within a target V/G range (hereinafter referred to as “T(VG)”), the ingot 30 or silicon wafer according to the present embodiment may predominantly include crystal defects having a size of 10 nm to 30 nm.

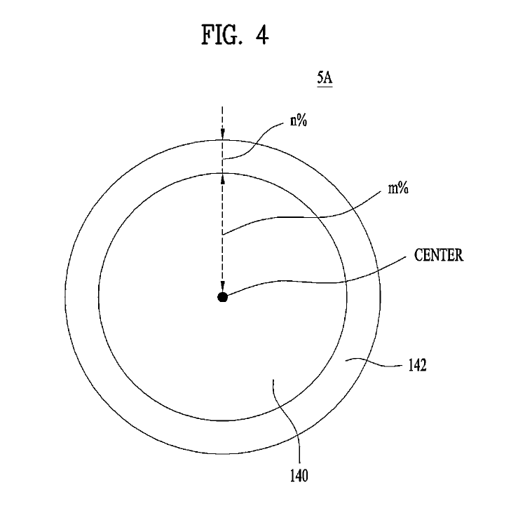

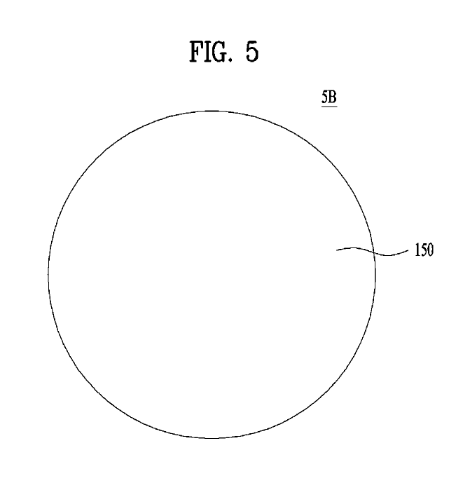

FIG. 4 is a plan view showing a single-crystal silicon ingot and wafer 5A according to one embodiment, and FIG. 5 is a plan view showing a single-crystal silicon ingot and wafer 5B according to another embodiment.

Upon growth of the ingot 30 at a V/G value designated by line 4-4′ within a T(VG) shown in FIG. 3, the ingot 30 or the silicon wafer 5A may exhibit crystal defect distribution as shown in FIG. 4. In this case, a transition region of the silicon wafer 5A is distributed in both a VDP region 142 and an IDP region 140.

Alternatively, upon growth of the ingot 30 at a V/G value designated by line 5-5′ within a T(VG) shown in FIG. 3, a silicon wafer 5B may have crystal defect distribution as shown in FIG. 5. In this case, a transition region of the silicon wafer 5B is distributed only in an IDP region 150. That is, the transition region of the silicon wafer 5B is not present in a VDP region.

Alternatively, upon growth of the ingot 30 at a V/G value designated by line 6-6′ within a T(VG) shown in FIG. 3, a transition region of a silicon wafer is distributed only in a VDP region. That is, the transition region of the silicon wafer is not distributed in an IDP region.

In conclusion, in the silicon wafer according to the present embodiment, the IDP region may occupy m % of the entire transition region as represented by the following equation 1, and the VDP region may occupy n % of the entire transition region as represented by the following equation 2.

m=100x Equation 1

n=100(1−x) Equation 2

Here, 0≦x≦1.

For example, on the basis of a diameter of the silicon wafer, the IDP region may occupy 70% or more of the entire transition region and the VDP region may occupy less than 30% of the entire transition region. In this case, in the silicon wafer 5A to include the transition region as exemplarily shown in FIG. 4, the VDP region may be located at the edge of the silicon wafer 5A and the IDP region may be located at the center inside the edge of the silicon wafer 5A. Alternatively, on the basis of a diameter of the silicon wafer, the VDP region may occupy 70% or more of the entire transition region and the IDP region may occupy less than 30% of the entire transition region. In this case, differently from the illustration of FIG. 4, as with the transition region, the IDP region may be located at the edge of the silicon wafer and the VDP region may be located at the center inside the edge of the silicon wafer. However, embodiments are not limited thereto, and as with the transition region of the silicon wafer, the VDP region and the IDP region may be located in various other manners.

Meanwhile, during growth of the ingot at a V/G value within the above-described T(VG), the ingot 30 may be grown at a V/G value deviated from an initially set T(VG) due to various factors. Therefore, it is necessary to evaluate whether the grown ingot 30 includes a transition region in which crystal defects having a desired size of 10 nm to 30 nm predominate. To this end, the present embodiment employs a Magics method.

With a typical Magics method, an image acquired by capturing a wafer sample is represented by different colors of pixels. In this case, it will be assumed from a pattern defined by the pixels that which one of growth, slicing, etching, and polishing processes causes defects of the wafer sample. As described above, the typical Magics method has simply been used to evaluate a source of defects. However, the applicant of this application has attempted to detect a size of crystal defects using a Magics method in the following manner.

Hereinafter, a method of evaluating, using a Magics method, whether crystal defects smaller than 30 nm, among crystal defects included in a wafer sample cut from the single-crystal silicon ingot 30 that is being grown, predominate (that is, whether the wafer sample includes a transition region) will be described with reference to the accompanying drawings.

First, while a single-crystal silicon ingot having a diameter of 12 inches (300 mm) is being grown, a wafer sample is prepared by cutting the ingot in a horizontal direction perpendicular to an ingot growth direction.

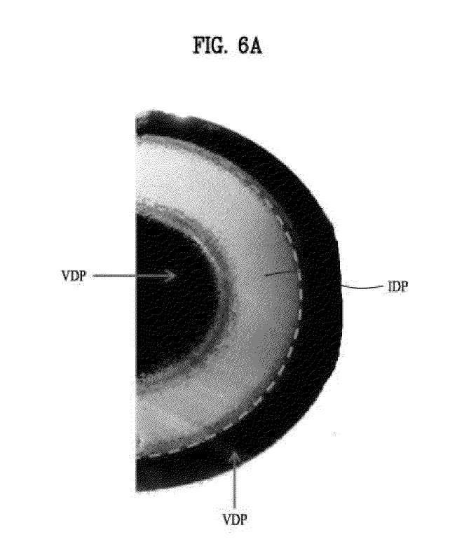

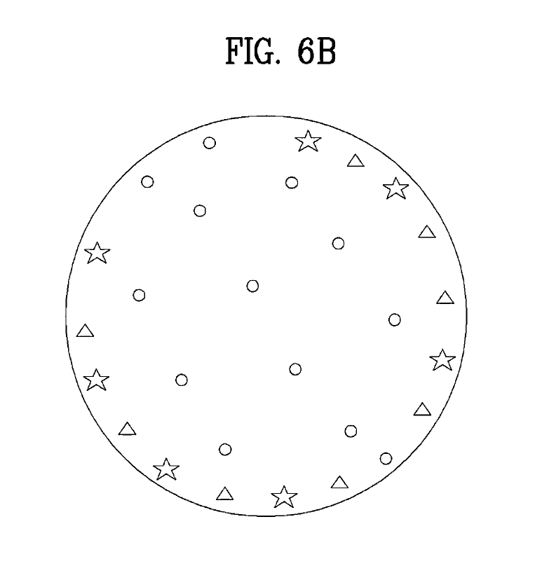

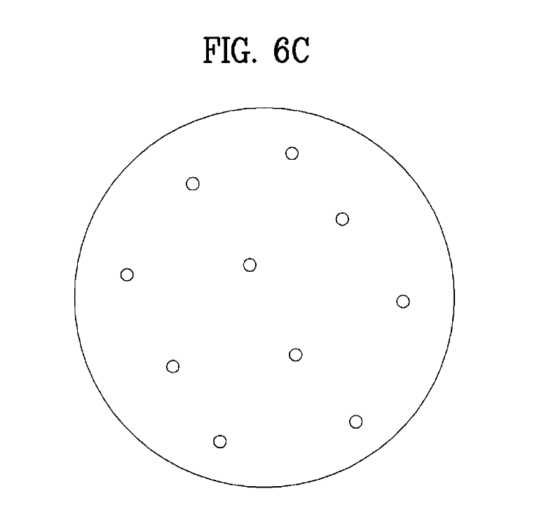

FIG. 6a is a plan view of a wafer sample after applying a Cu haze method to the wafer sample, and FIGS. 6b and 6c show images of wafer samples captured by a Magics method. FIGS. 6b and 6c show black and white images, although images acquired by a Magics method are represented by different colors of pixels. Therefore, for better understanding, color of pixels No. 1 is represented by ◯, color of pixels No. 2 is represented by ⋆, and color of pixels No. 3 is represented by Δ. In addition, although the images of FIGS. 6b and 6c show only a few pixels (i.e. pixels No. 1 to pixels No. 3), the number of pixels is not limited thereto and a greater number of pixels may be shown in a distinguishable manner.

With typical crystal defect evaluation methods, for example, a Cu haze method, as exemplarily shown in FIG. 6a, a VDP region of a wafer sample is simply shown in black and an IDP region is simply shown in white. Thus, the Cu haze method cannot evaluate how much crystal defects smaller than 30 nm among crystal defects included in the VDP region and the IDP region predominate. That is, with typical crystal defect evaluation methods, it is impossible to manufacture a silicon wafer including a transient region in which only crystal defects smaller than 30 nm, i.e. crystal defects having a size of 10 nm to 19 nm predominate.

However, according to the present embodiment, whether crystal defects smaller than 30 nm predominate in a wafer sample may be evaluated as follows.

First, an image having different colors of pixels (e.g., pixels No. 1 to pixels No. 3) as exemplarily shown in FIG. 6b or 6c is acquired by capturing a wafer sample with a camera (not shown).

In this case, the applicant of this application investigated volumes of crystal defects on a per pixel basis by reviewing the image shown in FIG. 6b or 6c with a Scanning Electron Microscope (SEM) and then observing the same with a Transmission Electro Microscope (TEM). That is, the applicant found from an image captured by a Magics method that sizes of crystal defects can be evaluated according to kinds of pixels.

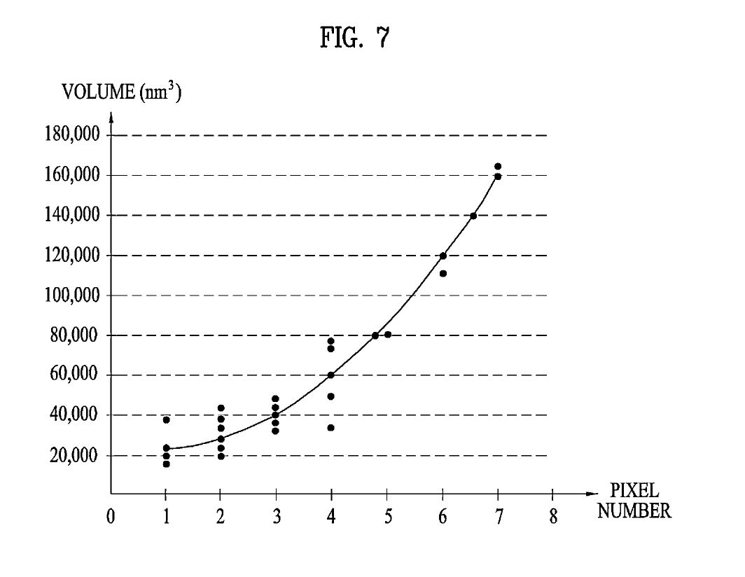

FIG. 7 is a TEM analysis graph of a relationship between volumes and pixels of an image acquired by a Magics method. In the graph, the abscissa represents pixel number and the ordinate represents volume. Here, a correlation coefficient (R²) is 0.9, and a correlation equation is y=3427.7x²−4700.4x+23968.

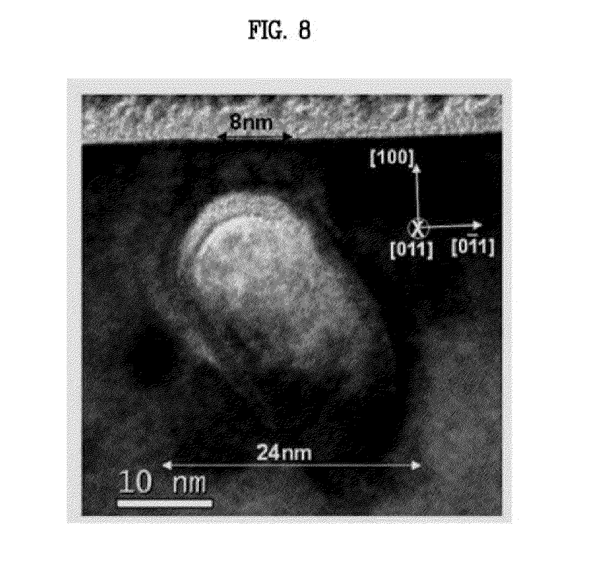

FIG. 8 shows an image of crystal defects corresponding to pixels No. 1 captured using a TEM. Here, [100], [011] and [0 1̅1] designate directions of a lattice.

A TEM is equipment capable of detecting sizes and kinds of crystal defects in the unit of Å and may be used to evaluate sizes of crystal defects on a per pixel basis via image captures as exemplarily shown in FIG. 8. In addition, it could be found by capturing numerous pixels with the TEM that sizes of defects on a per pixel basis are correlated as shown in FIG. 7. Referring to FIG. 7, it will be appreciated that pixels having a smaller number correspond to a smaller size of crystal defects. This implies that crystal defects are reduced in size as pixel number decreases. In addition, referring to FIG. 8, it will be appreciated that crystal defects of pixels No. 1 have a size of approximately 10 nm to 19 nm.

Accordingly, an accurate size of crystal defects smaller than 30 nm that could not be evaluated in the related art may be detected via pixels of an image captured by a Magics method.

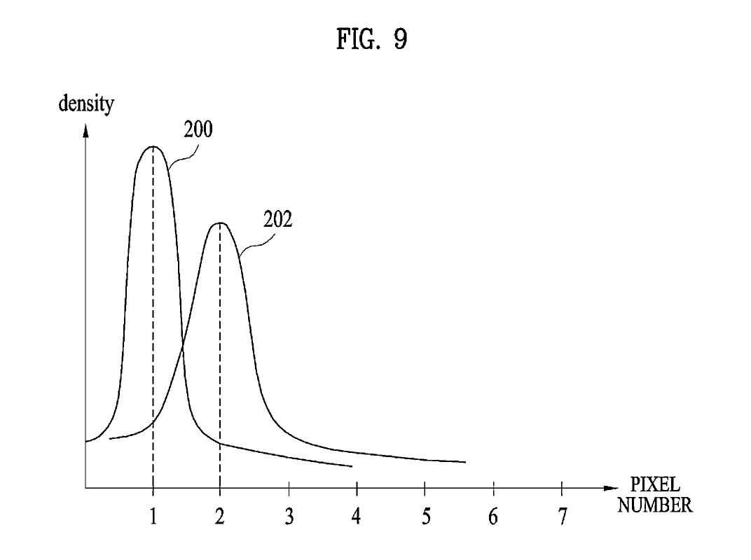

FIG. 9 is a graph showing a histogram of pixels. In the graph, the abscissa represents pixel number and the ordinate represents frequency (or density) of each pixel number.

A histogram of each pixel number as exemplarily shown in FIG. 9 is generated from a captured image of a wafer sample. Thereafter, sizes of crystal defects included in the wafer sample may be checked by evaluating a frequency of each pixel number based on the histogram.

Hereinafter, the manufacturing of a wafer sample in which crystal defects having a size corresponding to pixels No. 1 predominate is explained.

For example, in the image of the wafer sample shown in FIG. 6b, colors ◯, ⋆, Δ of pixels No. 1 to pixels No. 3 are shown in the edge, whereas only color C) of pixels No. 1 are shown in the center inside the edge. A histogram curve 200 shown in FIG. 9 is acquired from the image shown in FIG. 6b. In this case, since a frequency of pixels No. 1 is greater than a critical frequency, it is determined that the silicon wafer includes a transition region in which crystal defects having a size corresponding to pixels No. 1 predominate. Here, the critical frequency is determined based on the number of predominant defects. For example, when predominant defects occupy the aforementioned k %, the critical frequency refers to k % of the total number of pixels. That is, in this case, the wafer sample shown in FIG. 6b is accepted as a silicon wafer including a transition region in which crystal defects having a desired size predominate because the ingot 30 is grown at a V/G value within a T(VG).

Upon selection of a reduced V/G value within a T(VG), the image of the wafer sample as exemplarily shown in FIG. 6c may be acquired by a Magics method. In this case, the silicon wafer includes a transition region in which crystal defects of an IDP region predominate and thus is accepted.

However, referring to a histogram curve 202 shown in FIG. 9, a frequency of pixels No. 1 is less than a critical frequency and a frequency of pixels No. 2 is greater than the critical frequency. Therefore, the silicon wafer is not accepted because crystal defects having a size corresponding to pixels No. 2 predominate. Accordingly, when a V/G value deviates from the T(VG), the silicon wafer according to the present embodiment may be manufactured by growing the ingot 30 at a V/G value within a T(VG) by reducing the deviated V/G value by ΔV/G.

When a crystal lattice size on a per pixel number basis is predetermined as shown in FIG. 7 and a V/G value corresponding to each crystal defect size is predetermined, ΔV/G may be easily calculated. In FIG. 9, ΔV/G may be calculated by subtracting a V/G value corresponding to a crystal defect size of pixels No. 1 from a V/G value corresponding to a crystal defect size of pixels No. 2. In this case, when a frequency of pixels No. 1 becomes greater than a frequency of pixels No. 2 via adjustment of ΔV/G (202→200), distribution of the frequency increases. Thus, a value of ΔV/G may be determined in consideration of this frequency distribution increase.

As described above, according to the present embodiment, whether sizes of crystal defects included in a cut wafer sample are less than 30 nm, for example, within a range of 10 nm to 19 nm be evaluated by a Magics method. Accordingly, when a V/G value for growth of the single-crystal silicon ingot 30 deviates from a T(VG), accurate adjusting of the V/G value into the T(VG) is possible. Therefore, it will be appreciated that the silicon wafer according to the present embodiment includes only a transition region in which crystal defects having a size of 10 nm to 30 nm among crystal defects included in at least one of a VDP region and an IDP region predominate.

In addition, according to the present embodiment, upon evaluation of sizes of crystal defects included in a wafer sample using a Magics method, additional pre-treatment, such as heat treatment of the wafer sample, etc., is not necessary. Thus, rapid evaporation of the wafer sample may be accomplished such that the evaluation results are immediately fed back to growth of an ingot, which may result in reduced production time.

Hereinafter, an apparatus and method of growing a single-crystal silicon ingot for manufacturing the silicon wafer according to the above-described embodiment will be described with reference to the accompanying drawings. However, it will be appreciated that the apparatus and method of growing a single-crystal silicon ingot that will be described below may also be used to manufacture a general silicon wafer as well as the silicon wafer according to the present embodiment.

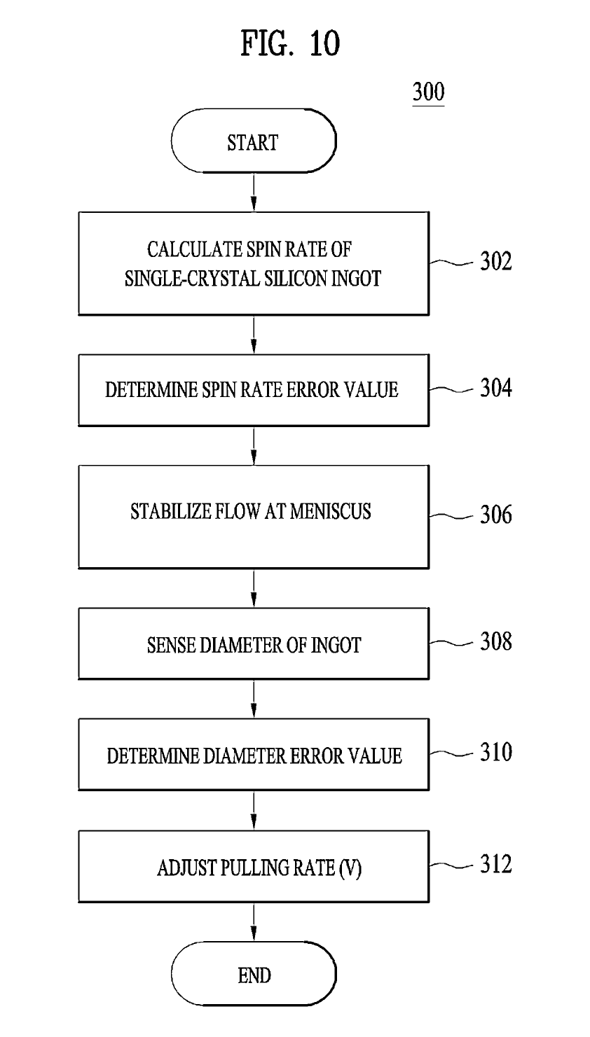

FIG. 10 is a flowchart explaining a method of growing a single-crystal silicon ingot according to one embodiment.

Referring to FIGS. 2 and 10, a spin rate of the single-crystal silicon ingot 30 is calculated (302). To this end, the spin rate calculator 92 may calculate a spin rate of the ingot 30 using a rotational velocity of the ingot 30 received from the hoist 40 and a diameter of the ingot 30 sensed by the sensor 90.

After Step 302, the first comparator 94 compares a target spin rate (TSR) with the spin rate calculated by the spin rate calculator 92, and outputs the comparison result, as a spin rate error value, to the flow rate controller 96 (304).

After Step 304, the flow rate controller 96 reduces, according to the spin rate error value received from the first comparator 94, a flow rate of the silicon melt 20 at a location 34 where a diameter of the single-crystal silicon ingot 30 to be grown is sensed (306). To this end, the flow rate controller 96 may control the hoist 40 and/or the support shaft drive unit 16 to reduce a flow rate. That is, the flow rate controller 96 controls a rotational velocity of the ingot 30 via the hoist 40 and controls a rotational velocity of the crucible 10 via the support shaft drive unit 16. Upon judgment based on the spin rate error value that the measured spin rate is greater than the target spin rate (TSR), the flow rate controller 96 reduces the flow rate. When the location 34 where the diameter is sensed corresponds to a meniscus of the silicon melt 20, the flow rate of the silicon melt 20 may be reduced to achieve stable flow at the meniscus.

After Step 306, the diameter sensor 90 senses a diameter of the single-crystal silicon ingot 30 (308).

After Step 308, the second comparator 110 compares the diameter sensed by the diameter sensor 90 with a target diameter (TD), and outputs the comparison result, as a diameter error value, to the hoist 40 (310).

After Step 310, the hoist 40 varies, according to the diameter error value, a pulling rate of the single-crystal silicon ingot 30 to be grown, and pulls the single-crystal silicon ingot 30 at the varied pulling rate while rotating the ingot (312). As such, the pulling rate of the single-crystal silicon ingot 30 to be grown may be adjusted according to the diameter error value.

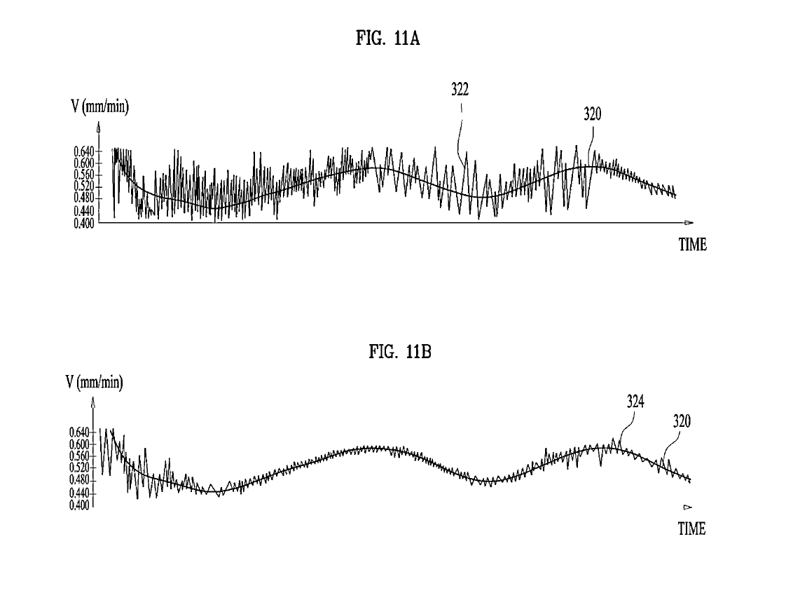

FIGS. 11a and 11b are graphs showing variation trace in the pulling rate (V) of the ingot 30. In the graph, the abscissa represents time and the ordinate represents pulling rate V.

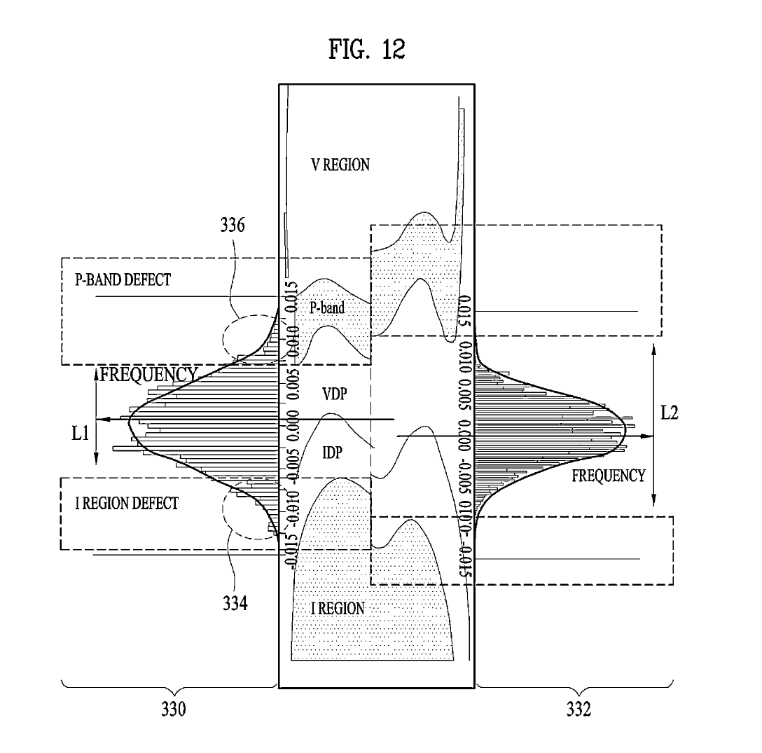

FIG. 12 is a view showing ranges of the pulling rate according to the related art and the present embodiment. Here, a P-band represents a boundary between a small void region and an O-band region shown in FIG. 2.

In the related art, the hoist 40 controls a pulling rate of the single-crystal silicon ingot 30 according to the diameter sensed by the diameter sensor 90. For example, when the diameter of the ingot 30 sensed by the diameter sensor 90 is greater than a target diameter (TD), the hoist 40 increases a pulling rate of the ingot 30 by a difference between the actually sensed diameter of the ingot 30 and the target diameter. However, when the sensed diameter of the diameter sensor 90 is less than the target diameter (TD), the hoist 40 reduces a pulling rate of the ingot 30 by a difference between the target diameter and the actually sensed diameter. In this case, the meniscus 34 where the diameter is sensed may become unstable due to nodes generated upon growth of the ingot 30 or due to effects of a flow rate of the silicon melt 20. When attempting to adjust the pulling rate based on the diameter actually sensed at the unstable meniscus 34, as exemplarily shown in FIG. 11a, a pulling rate variation width 322 may greatly deviate from a target variation width 320 within a T(VG). In this case, as exemplarily shown in FIG. 12, due to crystal defects 336 in a P-band region (between a small void region and an O-band region) and crystal defects 334 in a I region or V region, a frequency of ingots 30 or silicon wafers that should be disposed may increase (see reference numeral 330).

Differently from the related art, to solve the above-described problem, in the present embodiment, after stabilizing flow of the silicon melt at the meniscus 34 via the aforementioned Step 302 to Step 306 as described above, the diameter of the ingot is accurately sensed by the diameter sensor 90 and the pulling rate of the ingot is adjusted based on the accurately sensed value. Accordingly, a pulling rate variation width 324 deviated from a target variation width 320 is reduced as shown in FIG. 11b. Hence, referring to FIG. 12, a pulling rate range of the single-crystal silicon ingot 30 to be grown may considerably increase from a range L1 of 0.015 mm/min to 0.016 mm/min according to the related art to a range L2 of 0.010 mm/min to 0.030 mm/min, for example, 0.025 mm/min according to the present embodiment. Accordingly, as exemplarily shown in FIG. 12, in the present embodiment, it will be appreciated from a frequency of crystal defects in a wafer sample that there is no ingot 30 or silicon wafer that should be disposed due to crystal defects in the P region and the I region (see reference numeral 332). This may increase, on the basis of the same amount of silicon melt 20, productivity by 10% or more and a growth rate of the ingot 30 by 10% or more.

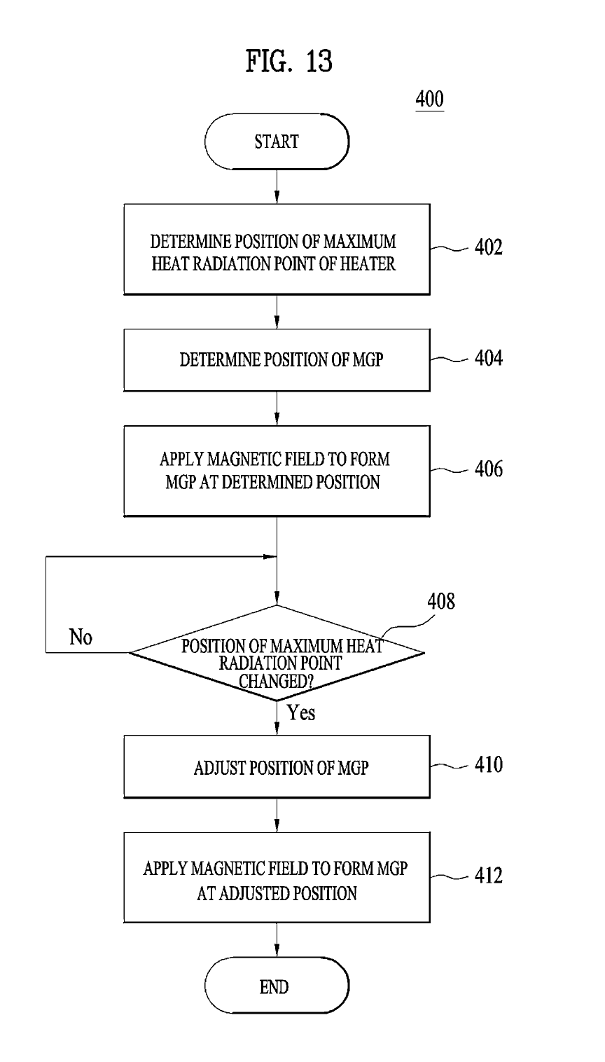

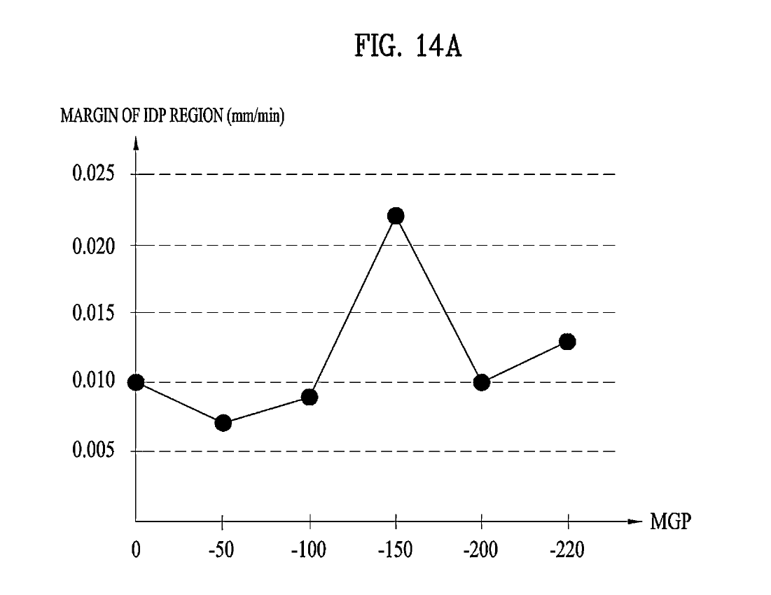

FIG. 13 is a flowchart explaining a method of growing a single-crystal silicon ingot according to another embodiment.

Referring to FIGS. 2 and 13, the first controller 120 determines a position 62 of a maximum heat radiation point of the heater 60 (402).

After Step 402, the second controller 130 determines a position of a Maximum Gauss Plane (MGP) according to the determined position 62 of the maximum heat radiation point of the heater 60, the determined position 62 being receiving from the first controller 120 (404). Here, the MGP refers to a region where a horizontal component of a magnetic field generated by the magnetic field generator 80 becomes the maximum. The magnetic field generator 80 is thermally isolated from the heater 60 by the insulator 70.

The heater 60 may exhibit uniform heat radiation in the vertical direction and may be adjusted in heat radiation in the vertical direction. Upon uniform heat radiation in the vertical direction by the heater 60, the maximum heat radiation point is located at or slightly above the center of the heater 60. However, when heat radiation of the heater 60 is adjustable in the vertical direction, the maximum heat radiation point may be optionally adjusted.

After Step 404, the second controller 130 controls the magnetic field generator 80 to apply a magnetic field to the crucible 10 so as to create an MGP at the determined position (406).

Thereafter, when a position of the maximum heat radiation point is changed (408), a position of the MGP is adjusted according to the changed position 62 of the maximum heat radiation point (410). The first controller 120 may control the heater 60 to change the position 62 of the maximum heat radiation point. When the heater 60 is moved, the position 62 of the maximum heat radiation point may be changed. The second controller 130 checks the position 62 of the maximum heat radiation point changed by the first controller 120, and adjusts a position where the MGP will be created according to the changed position.

After Step 410, the second controller 130 controls the magnetic field generator 80 to apply a magnetic field to the crucible 10 so as to create an MGP at the adjusted position (412).

In some embodiments, the MGP may be determined to be located lower than the position 62 of the maximum heat radiation point. For example, the MGP may be located lower than the position 62 of the maximum heat radiation point by 20% to 40% on the basis of an interface of the silicon melt 20. That is, assuming that the position 62 of the maximum heat radiation point is spaced apart from the interface of the silicon melt 20 by a first distance D1, the MGP may be located with being spaced apart from the interface of the silicon melt 20 by a second distance D2 that is smaller than the first distance D1 by 20% to 40%. The second distance D2 may be within a range of 50 mm to 300 mm, for example, 150 mm.

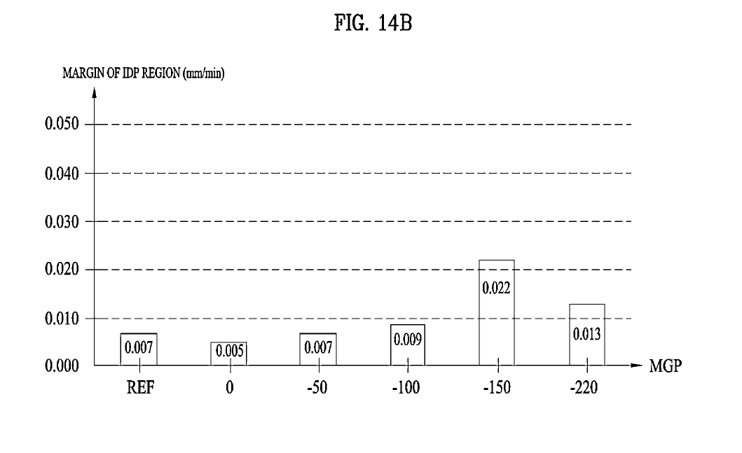

FIG. 14a shows the maximum value of a margin of an IDP region based on an MGP position value, and FIG. 14b shows a 70% value of the maximum value of a margin of an IDP region based on an MGP position value. In each graph, the abscissa represents MGP position value. The MGP position value is zero at the interface of the silicon melt 20 and decreases into a negative value downward of the interface. In FIG. 14b, “REF” designates a reference value for comparison with an MGP according to the present embodiment.

Referring to FIGS. 14a and 14b, it will be appreciated that the MGP may be located within a range of −50 mm to −300 mm, and a margin of an IDP region becomes the maximum when the MGP is located at −150 mm.

Meanwhile, convection of the silicon melt 20 may be controlled by adjusting a position of the MGP and the position 62 of the maximum heat radiation point and may also be controlled by the strength of a magnetic field applied by the magnetic field generator 80. For example, it will be appreciated that the magnetic field applied to the crucible 10 by the magnetic field generator 80 may have a strength of 2000 gauss to 3400 gauss and a margin of an IDP region becomes the maximum at the strength of 2800 gauss.

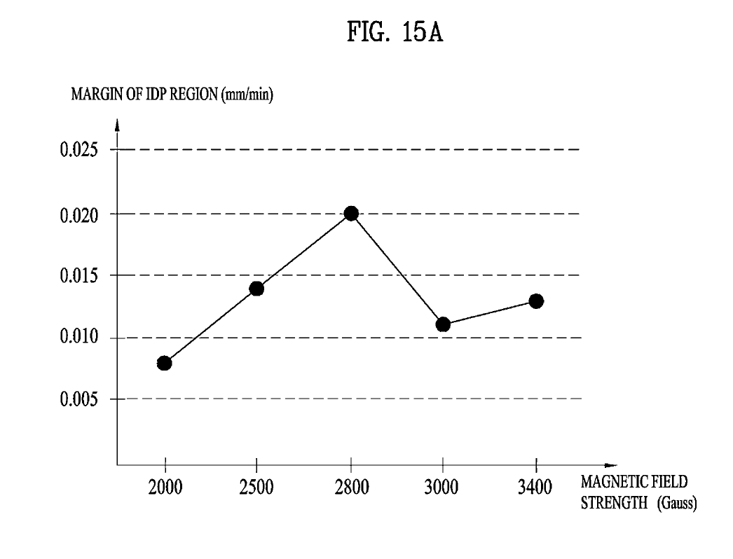

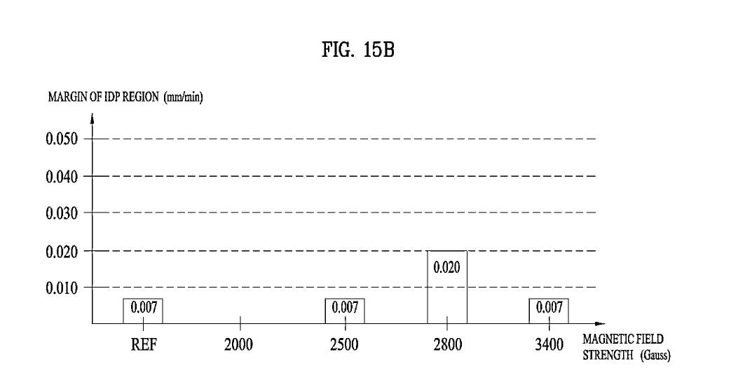

FIG. 15a shows the maximum value of a margin of an IDP region based on the strength of a magnetic field, and FIG. 15b shows a 70% value of the maximum value of a margin of an IDP region based on the strength of a magnetic field. In each graph, the ordinate represents margin of an IDP region, and the abscissa represents strength of a magnetic field in gauss. In FIG. 15b, “REF” designates a reference value for comparison with a gauss value according to the present embodiment.

Referring to FIGS. 15a and 15b, when the strength of a magnetic field is 2800 gauss, a margin of an IDP region may increase from 0.007 mm/min to a range of 0.010 mm/min to 0.030 mm/min. For example, the margin of the IDP region may be enhanced to a range of 0.020 mm/min to 0.022 mm/min.

This increase in the margin of the IDP region causes extension of a temperature range of 1250° C. to 1420° C. for formation of the IDP region, which ensures considerably easier manufacture of the above-described silicon wafer.

When a spin rate of the single-crystal silicon ingot 30 is changed, generally, a convexity of the interface of the silicon melt 20, a temperature gradient in a growth direction of the ingot 30 (G=Gs+Gm) (here, Gs is a temperature gradient of the ingot and Gm is a temperature gradient of the silicon melt 20), a radial temperature gradient difference of the ingot 30 at a contact region between the ingot 30 and the silicon melt 20 (ΔG=Gse−Gsc)(here, Gse and Gsc are respectively temperature gradients at the lower edge and the center of the ingot 30), a concentration of oxygen included in the ingot 30, a size of an overcooling region between the ingot 30 and the silicon melt 20 and the like are changed. For example, a greater spin rate of the silicon ingot 30 causes a greater convexity of the interface of the silicon melt 20, a greater temperature gradient G, a smaller temperature gradient difference ΔG, and a lower concentration of oxygen, which enables production of a high-quality ingot 30, but causes difficulty in control of a pulling rate. Conversely, a smaller spin rate of the silicon ingot 30 causes a flat interface of the silicon melt 20, a smaller temperature gradient G, a greater temperature gradient difference ΔG, and a higher concentration of oxygen, which may potentially cause production of a poor-quality ingot 30, but ensures easy control of a pulling rate. However, these relationships may break down due to a magnetic field. In addition, generally, the silicon melt 20 shown in FIG. 2 may undergo convection in a direction designated by arrow 22 via rotation of the ingot 30 and convection in a direction designated by arrow 24 via rotation of the crucible 10. However, the silicon melt 20 may undergo isolated upper and lower convection on the basis of the MGP.

Differently from the related art, according to the above-described present embodiment, an MGP is determined according to a position of a maximum heat radiation point in consideration of convection of the silicon melt and convection of the silicon melt 20 is controlled by appropriately adjusting the strength of a magnetic field. Hence, it is possible to compensate for the above-described problems that may be caused upon change of a spin rate. That is, when the MGP is located lower than the position 62 of the maximum heat radiation point from the interface of the silicon melt 20 by 20% to 40%, convection in a direction designated by the arrow 22 becomes strong toward the center of the ingot 30, which enables acquisition of a vacancy-interstitial recombination section and, consequently, increases a margin of an IDP region.

In the present embodiment, to grow a silicon wafer or ingot including a transition region in which crystal defects having a size of 10 nm to 30 nm predominate, the apparatus as exemplarily shown in FIG. 2 has been used. However, the growth apparatus shown in FIG. 2 to perform the above-described methods shown in FIGS. 10 and 13 is merely given by way of example and, of course, an Automatic Growing Controller (AGC) (not shown), an Automatic Temperature Controller (ATC) (not shown) or the like may be used to perform each step.

In addition, the above-described methods of growing a single-crystal silicon ingot shown in FIGS. 10 and 13 may be used simultaneously, or any of these methods may be used alone. In addition, to manufacture the silicon wafer according to the present embodiment, in addition to a spin rate of the single-crystal silicon ingot 30, an MGP, the strength of a magnetic field, a position of the maximum heat radiation point, pressure/flow rate of an inert gas, such as argon gas, etc. that is cooling gas, a gap between the heat shield member 50 and the interface of the silicon melt 20, shape of the heat shield member 50, the number of heaters 60, and a rotational velocity of the crucible 10 may also be used.

Although the preferred embodiments have been shown and described above, the embodiments are merely given by way of example and the disclosure is not limited to the above-described specific embodiments. Thus, it will be apparent to those skilled in the art that various modifications and variations not described herein can be made without departing from the gist of the embodiments. For example, the respective components of the embodiments as described above in detail may be used in modified forms. In addition, differences related to these modifications and application should be construed as being included in the scope of the present invention as defined by the accompanying claims.

### INDUSTRIAL APPLICABILITY

The present embodiment may be used for production of high-quality single-crystal silicon ingots and wafers for semiconductors which include micro crystal defects smaller than 30 nm.

1. A single-crystal silicon ingot and wafer comprising a transition region having predominant crystal defects having a size of 10 nm to 30 nm among crystal defects included in at least one of a vacancy predominant non-defective region and an interstitial predominant non-defective region.

2. The single-crystal silicon ingot and wafer according to claim 1, wherein the crystal defects having a size of 10 nm to 30 nm make up above 50% of all crystal defects included in the transition region.

3. The single-crystal silicon ingot and wafer according to claim 1, wherein the crystal defects having a size of 10 nm to 30 nm make up 70% or more of all crystal defects included in the transition region.

4. The single-crystal silicon ingot and wafer according to claim 1, wherein the transition region include no ring-shaped oxidation induced stacking faults.

5.-6. (canceled)

7. The single-crystal silicon ingot and wafer according to claim 1, wherein the interstitial predominant non-defective region occupies 100x % of the entire transition region (here, 0≦x≦1), and the vacancy predominant non-defective region occupies 100(1−x) % of the entire transition region, in the single-crystal silicon ingot and wafer.

8. The single-crystal silicon ingot and wafer according to claim 1, wherein the interstitial predominant non-defective region occupies 70% or more of the entire transition region on the basis of a diameter of the single-crystal silicon ingot and wafer.

9. The single-crystal silicon ingot and wafer according to claim 1, wherein the vacancy predominant non-defective region occupies 30% or less of the entire transition region on the basis of a diameter of the single-crystal silicon ingot and wafer.

10. (canceled)

11. The single-crystal silicon ingot and wafer according to claim 1, wherein the size of the crystal defects included in the transition region is detectable by a Magics method.

12. The single-crystal silicon ingot and wafer according to claim 11, wherein the size of the crystal defects included in the transition region is detectable by the Magics method, under a state without thermal treatment of the single-crystal silicon ingot and wafer.

13. (canceled)

14. An apparatus of growing a single-crystal silicon ingot, the apparatus comprising:
a crucible configured to receive a silicon melt therein;
a heater installed around the crucible to apply heat to the crucible; and
a magnetic field generator configured to apply a magnetic field to the crucible such that a maximum magnetic plane (MGP) is created at a position determined according to a position of a maximum heat radiation point of the heater.

15. (canceled)

16. The apparatus according to claim 14, wherein the heater is configured to adjust the radiation amount of heat in the vertical direction.

17. The apparatus according to claim 14, wherein the MGP is located lower than the position of the maximum heat radiation point.

18. The apparatus according to claim 17, wherein the MGP is located lower than the position of the maximum heat radiation point by 20% to 40% on the basis of an interface of the silicon melt.

19. The apparatus according to claim 14, wherein the MGP is located lower than the interface of the silicon melt by 50 mm to 300 mm.

20. The apparatus according to claim 14, wherein the single-crystal silicon ingot to be grown has a target pulling rate range of 0.010 mm/min to 0.030 mm/min.

21. A method of growing a single-crystal silicon ingot performed by an apparatus of growing a single-crystal silicon ingot, the apparatus comprising a crucible configured to receive a silicon melt therein, a heater installed around the crucible to apply heat to the crucible and a magnetic field generator configured to apply a magnetic field to the crucible, the method comprising:
determining a position of a maximum heat radiation point of the heater;
determining a position of a maximum magnetic plane (MGP) according to the determined position of the maximum heat radiation point; and
applying the magnetic field to the crucible so as to create the MGP at the determined position.

22. (canceled)

23. The method according to claim 21, wherein the magnetic field is applied to the crucible so as to create the MGP at a position lower than the position of the maximum heat radiation point.

24. The method according to claim 21, wherein the magnetic field is applied to the crucible so as to create the MGP at a position lower than the position of the maximum heat radiation point by 20% to 40% on the basis of an interface of the silicon melt.

25. The method according to claim 21, wherein the magnetic field is applied to the crucible so as to create the MGP at a position lower than an interface of the silicon melt by 50 mm to 300 mm.

26. The method according to claim 25, wherein the single-crystal silicon ingot to be grown has a target pulling rate range of 0.010 mm/min to 0.030 mm/min.

27.-33. (canceled)
